(19) United States
(12) Patent Application Publication
(10) Pub. No.: US 2006/0258136 A1
(43) Pub. Date: Nov. 16, 2006

(54) Method of forming a metal trace

(76) Inventors: Guangjin Li, San Diego, CA (US); Peng Chen, Singapore (SG); Qiong Chen, Singapore (SG)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/128,016

(22) Filed: May 11, 2005

(51) Int. Cl. H01L 21/44

(52) U.S. Cl. 438/612; 438/674; 438/660

(57) ABSTRACT

Disclosed is a method of forming a metal trace on a substrate. The method includes inkjet printing a chemical ink comprising a metal containing compound on the substrate surface to form an ink drop thereon, and heating the substrate to a suitable elevated temperature. The ink drop undergoes at least one of decomposition and reduction due to the substrate temperature to form a metal on the substrate in a controlled atmosphere.

### BACKGROUND

The present invention relates to method of forming a metal trace on a substrate and more particularly to a method of forming a conductive metal trace on a substrate by inkjet printing.

Recently, developments in polymeric electronics gained a lot of interest because of the potential in producing low cost and flexible electronic devices. Conventional methods typically involve subtractive methods with complex and expensive processes like photolithography, thin film coating, and plating.

A number of approaches exist such as direct-write metals with laser. In direct writing processes, conductive metals are selectively deposited on a substrate by means of a laser. Much effort has been undertaken in attempting to produce acceptable individual metal features in electronic components or circuits by such a direct laser writing process. Normally, a device is prepared for subsequent direct laser writing by a spin-coating process which applies a uniform film over a surface.

Spin-coating is a known process used for applying a thin film, such as a metal, to a substrate in the manufacture of circuits. A typical spin-coating process involves depositing a small puddle of a fluid resin onto the center of the substrate and then spinning the substrate at high speed. However, spin-coating processes generally involve a relatively high cost of materials and a further washing process to remove unwanted material.

Another disadvantage of circuit manufacture by direct laser writing is that the width of a deposited metal trace is limited by thermal effects in the laser beam. Presently, even if a laser beam is focused to a diameter of about 20 μm the achievable minimum trace width is about 40 μm.

Another known circuit manufacture process involves etching. A number of variations of etching methods are known, such as wet etching (whereby material is dissolved when immersed in a chemical solution), and dry etching (whereby material is sputtered or dissolved using reactive ions or a vapor phase etchant). However, these methods have significant disadvantages such as a requirement to use a mask of the desired circuit layout pattern that can withstand the etching process. Generally, etching processes and use of masks are considered relatively expensive and require longer turn around times in the manufacture of circuitry.

However, there still exists the need for a system which can be used for easy and convenient metallization of substrates. The present invention addresses this need.

### SUMMARY

In one aspect, the present invention provides a method of forming a metal trace on a substrate. The method includes inkjet printing a chemical ink comprising a metal containing compound suitable to be printed on the substrate to form an ink drop thereon, and heating the substrate to a suitable elevated temperature. The ink drop decomposes or is reduced due to the substrate temperature to form a metal on the substrate in a controlled atmosphere. These and other features of the invention will be better understood in light of the following drawings and detailed description.

### BRIEF DESCRIPTION OF THE DRAWINGS

FIG. 1 shows a system that can be used for carrying out a method of forming a metal trace according to an embodiment of the present invention, and

FIG. 2 shows a flow chart of a method of forming a metal trace according to an embodiment of the present invention.

### DETAILED DESCRIPTION

The present invention provides a novel method to print a metal trace onto a substrate. The principle of the method is to print a metal containing chemical onto a substrate that is maintained at a suitable elevated temperature and/or any other conditions which provides for the release of the pure metal from the metal containing chemical and subsequently to the formation of a metal trace.

Therefore, in a first aspect, there is provided a method of forming a metal trace on a substrate. The method includes preparing a chemical ink comprising a metal containing compound suitable to be printed on the substrate surface, heating the substrate to a suitable elevated temperature and printing the chemical ink using inkjet printing onto the substrate thus forming an ink drop thereon. The ink drop formed on the substrate decomposes or is reduced at least in part due to the substrate temperature to form a metal dot on the substrate in a controlled atmosphere.

In accordance with the first aspect, a chemical ink is provided that is able to be printed onto a substrate and subsequently form a desired metal trace. The chemical ink may include at least one organometallic compound as metal containing compound. This organometalic compound is typically able to decompose and/or to be chemically reduced under the chosen reaction conditions to form a pure metal.

In one embodiment of the present invention, the chemical ink consists of only one organometallic compound to form a metal trace consisting of one metal on the substrate surface. However, in another embodiment, it is also possible that the chemical ink is composed of two or more organometallic compounds. In this case, the individual compounds of this mixture of organometallic compounds generally are dissolvable in each other to typically form one uniform mixture; however, non-uniform mixtures may also be utilized. In a further embodiment described in detail below the ink includes a solvent in which the organometallic compound is dissolved. Typically, and irrespective of the exact nature of the chemical ink, the metal trace formed via printing of the chemical ink is electrically conducting so that the method can be used to form any desired pattern of metal traces.

The term “organometallic compound” as used herein includes compounds of a transition metal of group 3 to 10 of the Periodic Table (IUPAC) or of group 13 of the Periodic Table (IUPAC) metal which metal bears at least one organic (coordination) ligand. Organometallic compounds may include a metal selected from, but not limited to, Al, Cu, Au, Ni, Pt, Ir, Os, Pd, Mo, W and Cr. In one embodiment, the organometallic compound is selected from an aluminum, copper, gold, nickel or platinum organometallic compound.

An organic ligand present in an organometallic compound in accordance with an embodiment can be any organic compound which can be either directly bound to the metal atom or coordinated with the metal atom wherein the bond between the ligand and the metal atom should be easily broken up upon heating. Examples of such organic ligands are, but not limited to, alkyl groups, ketones, diketones, aryl, carbonyl groups. Specific examples are methyl, ethyl, propyl, butyl, pentyl and isomers thereof, acetylacetone, cyclopentadienyl, or carbonyl, to name only a few.

In some embodiments, aluminum compounds are used in the chemical ink. In some of these embodiments, the aluminum compounds are compounds of the general formula Al(R¹)₃, wherein R¹ is independently selected from hydrogen, methyl, ethyl, propyl, butyl, pentyl and isomers thereof. Examples of such compounds are trimethylaluminium, triethylaluminium, triisobutylaluminium (TIBA), diisobutylaluminium hydride (DIBAH) and tripropylaluminium. The properties of these last mentioned compounds, such as melting point (Mp), boiling point (Bp) and decomposition temperature, are shown in Table 1.

TABLE 1

| | | | | Decomposition |
|---|---|---|---|---|
| Compound | Formula | Mp (° C.) | Bp (° C.) | (° C.) |
| Trimethyl-Al | (CH₃)₃Al | 15 | 126 | 250-450 |
| Triethyl-Al | (C₂H₅)₃Al | −58 | 194 | >300 |
| Triisobutyl-Al | (i-C₄H₉)₃Al | 4 | 130 | 260 |
| Diisobutyl-Al | (i-C₄H₉)₂AlH | −70 | 118 | 260 |
| hydride | | | | |
| Tripropyl-Al | (C₃H₇)₃Al | −107 | 82-84 | — |

Examples of suitable copper compounds which can be used include, but are not limited to, compounds of the formula CpCuP(R²)₃, wherein P is phosphor, Cp is cyclopentadienyl, and R² is independently selected from hydrogen, methyl, ethyl, propyl, butyl, pentyl and isomers thereof. Other suitable copper compounds include β-diketones of Cu, e.g. copper formate or copper acetylacetonate [Cu(acac)₂],

Examples of gold compounds which can be used include, but are not limited to, gold methyl compounds. For example, dimethylgold-(III)-acetylacetonate [Me₂Au(acac)], dimethylgold-(III)-trifluoacetylacetonate [Me₂Au(tfac)], or dimethylgold-(III)-hexafluoroacetylacetonate [Me₂Au(hfac)] can be used.

Ni compounds which can be used include, but are not limited to, Ni(CO)₄, Ni(R²)₂ or Ni(C₅HF₆O₂)₂, wherein R² can be methyl, ethyl, cyclopentadienyl or the like.

In another embodiment, the organometallic compound is selected from the group that includes dimethylethylamine alane, Pt(CH₂(COCH₃)₂), and CpPt(R³)₃, wherein Pt is platinum, Cp is cyclopentadienyl, and R³ is independently selected from the group that includes, but is not limited to, methyl, ethyl, propyl, butyl, pentyl and isomers thereof.

It should be noted here that the described embodiments are by no means limited to the compounds mentioned above. Rather any other metal containing compound that can be formulated as a chemical ink that releases the pure metal upon decomposition and/or reduction and that has comparable physico-chemical properties to the compounds described with reference to the above embodiments can be used for forming a metal trace. For example, making reference to gold containing compounds, a suitable compound may be an organometallic gold compound that has comparable physico-chemical properties as dimethylgold-(III)-acetylacetonate which can be incorporated into a suitable solvent, is stable at room temperature, has a similar melting point and a similar decomposition temperature. Alternatively, making as a further example reference to aluminum containing compounds, a suitable organometallic aluminum compound may be any such aluminum compound that, for example, is a liquid at room temperature, has a boiling point higher than about 80° C. and a decomposition temperature of up to about 400° C.

As long as the organometallic compound is in a liquid form under the above delineated conditions, the organometallic compound can be used in its pure form to be filled into a dispensing device such as an inkjet print head of the used ink jet printer. For example, a compound such as triisobutylaluminum [Al(C₄H₉)₂₃] or triethylaluminum [Al(C₂H₅)₃] can be used in pure form as chemical ink as the melting point is around 4° C. and −58° C., respectively, and the boiling point is at 130° C. and 194° C., respectively (cf. Table 1).

In another embodiment, a solvent can be used to dissolve the organometallic compound, if the organometallic compound is in a solid form or in a viscous liquid form under the conditions of the printing process. This solvent may be an organic solvent, a water-based organic solvent, pure water or mixtures of water with various organic solvents including the water based organic solvent. Examples of such water-based organic solvents include, but are not limited to, nitrogen-containing ketones, pentandiols and triols. In some embodiments 2-pyrrolidone, N-methyl-pyrrolid-2-one (NMP), 1,2-pentanediol, 1,5-pentanediol or glycerol may be used as water based solvent. Furthermore, in order to achieve proper drop ejection of the chemical ink from printer nozzles, the physical properties of the chemical ink can be optimized, i.e. the surface tension and viscosity of the chemical ink can be adapted by the use of a solvent in any particular way. According to the chosen solvent, it is possible to vary the temperatures of the substrate needed for the decomposition of the metal containing compound.

Generally, any suitable inkjet technology, including both drop on demand and continuous inkjet technologies, can be used as (micro)printing tool, i.e. an inkjet printer can be used to print the metal containing compounds onto any desired surface of a given substrate. In an embodiment, the inkjet printer used may be a thermal inkjet printer, for example a conventional Hewlett-Packard desk-jet printer. Other types of inkjet printers such as a piezo inkjet printer may be also used.

In an embodiment, a multiple-nozzle rasterization technique is implemented. According to this technique, the printer head of the inkjet printer includes a plurality, sometimes hundreds of small nozzles that are capable of depositing fine precise droplets of the chemical ink onto the substrate surface. As previously explained above, in an embodiment both thermal and piezo-type inkjet technologies can be used for deposition of the metal trace onto the substrate. In the case of thermal inkjet technology, ink is ejected out of nozzles by rapid heating of small heaters on printheads. In the case of piezo-type ink jet, small ink drops are ejected by mechanical forces induced by the piezo phenomenon.

In one embodiment, microprocessor-controlled inkjet printing is used. Microprocessor controlled inkjet printing has a number of advantages. Rapid prototyping is possible because once a circuit has been designed, either by traditional layout or with a computer-aided design system, the circuit (i.e. metal traces forming the circuit) can be printed immediately without any significant time lag involved in other processes. The uniformity of the thickness of traces (which are usually films) deposited can be easily varied for different parts of the circuits. In addition, inkjet printing can be substantially computer controlled. Thus, a high degree of automation is possible with potential savings in cost and improved throughput compared to conventional techniques.

The substrate can be any substrate capable of binding the chemical ink and the respective metal dot. Furthermore, the substrate should be chemically and mechanically stable when heated to the elevated temperatures. The substrate may be an inorganic substrate or an organic substrate or a combination thereof. Inorganic substrates may include glass or a ceramic. Organic substrates may include a polymeric material such as polyimide (films), polycarbonate (films) or polymeric silicon compounds. Other suitable organic substrates include paper.

According to an embodiment, the substrate is heated to a desired temperature so that the chemical ink printed onto the substrate surface can be decomposed to form the metal dot. The temperature is typically in a range capable of decomposing or reducing the organometallic compound of the chemical ink. Therefore, the lower end of the temperature range is usually above the decomposition temperature of the organometallic compound. The upper end of the temperature range is usually chosen such that the substrate or the metal dots already formed on the surface of the substrate will not be negatively affected by this temperature. Generally, the substrate is heated to temperatures in the range of about 100° C. to about 500° C. In some embodiments, the substrate is heated to temperatures from about 150° C. to about 450° C. For example, if Cu compounds are used as chemical ink, temperatures in the range of about 250° C. to about 350° C. are typically chosen. Likewise, if an aluminum compound as one of those given as illustrative examples in Table 1 is used, the substrate may typically be heated to a temperature of about 300° C. to about 350° C. Additionally, the substrate can be heated by any suitable means, for example, by a hotplate or infrared radiation or an electrical current.

In an embodiment the method can be carried out under anhydrous and oxygen-free conditions. The use of such conditions is generally beneficial to the resistivity of the formed metal trace and thus also to the resistivity of an electronic circuitry that may be formed from the metal traces. For example, to avoid unwanted side reactions the process can be run in an inert atmosphere such as, but not limited to, a nitrogen atmosphere, or a noble gas atmosphere such as a argon or xenon atmosphere. The inert atmosphere can also be formed by mixtures of inert gases. In one embodiment, a nitrogen atmosphere is used as such an inert atmosphere. Furthermore, it is also possible to carry out the method under a reducing atmosphere. The reducing atmosphere can be created by adding a reducing gas to an inert gas. One example for such a reducing atmosphere is a H₂-enriched nitrogen atmosphere. Such a reducing atmosphere can cause or promote the formation of the pure metal. For example, if a nickel compound such as Ni(cyclopentadienyl)₂ (Ni(cp)₂) is used, H₂ present in the reaction chamber reacts with Ni(cp)₂ under elevated temperatures (for example 200° C.) to yield nickel as the pure metal and benzene.

The method can be carried out at, above or below ambient pressure although the process generally is performed at ambient pressure. However, if it desired to remove decomposed parts of the chemical ink which are not linked to the substrate surface or to remove a reaction product formed in the deposition process (for example, the benzene mentioned above, or carbon monoxide if Ni(CO)₄ is used as precursor molecule) the reaction chamber in which the method is carried out can be evacuated after the deposition of the ink droplets on the substrate. Evacuation of the reaction chamber, i.e. reducing the pressure in the reaction chamber, can also be carried out in order to facilitate removal/evaporation of residual solvent if the metal containing compound was dissolved in such a solvent.

By means of the present method any desired metal trace can be formed on a given substrate. For example, it is possible to form only a single trace on a semiconductor substrate in order to obtain an electrical contact pad on this substrate. It is also possible to use the ink jet printing to form complex patterns comprising numerous individual metal traces on the substrate, for example to print an entire electronic circuit onto a given substrate. Another example of a conductive structure that can be formed using the method of the invention is the coil of a radio frequency identification (RF ID) tag.

The thickness of the formed metal trace can be controlled by repeated printing on the substrate. For example, a conductive trace layer can be built up, but is not limited, to a height of about 10 to 30 μm, for example about 15 to 25 μm, by repeated printing. By printing several layers of the trace, it is possible to obtain the desired thickness of the conductive trace should a single layer not satisfy the conductivity requirement of a desired electronic product.

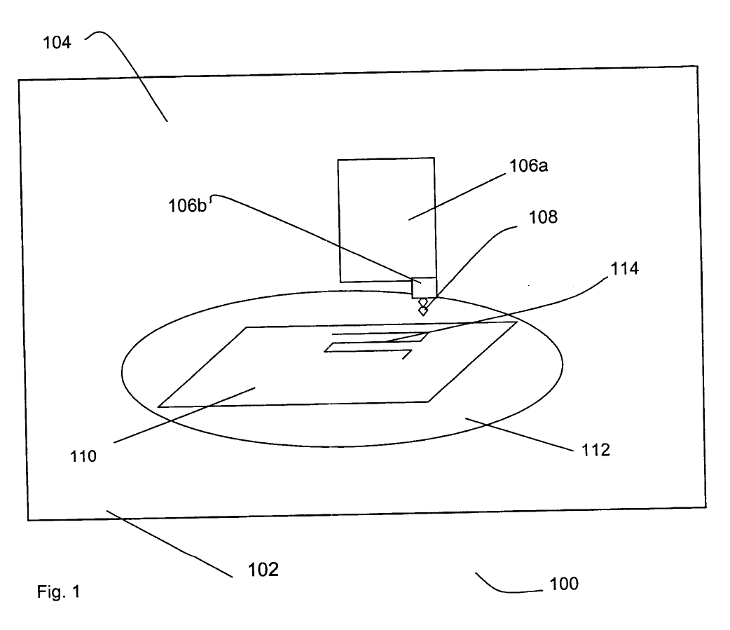

FIG. 1 illustrates one embodiment of a system 100. The system 100 includes a reaction chamber 102 in which a controlled atmosphere 104 is created. The controlled atmosphere 104 may be a chemically inert atmosphere such as a nitrogen atmosphere or a reducing atmosphere such as a mixture of hydrogen and nitrogen gas, depending on the chemical ink to be used for formation of a metal trace. The system further includes an ink jet printing device (not shown for clarity reasons) which has an ink cartridge 106a filled with chemical ink and a printhead 106b. When in use, droplets 108 of the chemical ink are dispensed from the printhead 106b of ink cartridge 106a onto a substrate 110. The substrate 110 may be any suitable substrate on which a metal trace is to be formed. The substrate is held in place by a support 112. Either the support 112 is moveable in the plane substantially perpendicular to the printhead 106b in order to move the substrate and to allow printing of a metal trace or patterns of metal traces, or the ink cartridge 106a is moveable to move the printhead 106b relative to the substrate. In still other embodiments, various combinations of moving the substrate and the printhead also may be utilized. The support 112 further includes a heating element that heats the substrate to a temperature that is suitable for decomposition of the metal containing chemical ink and formation of a metal trace 114.

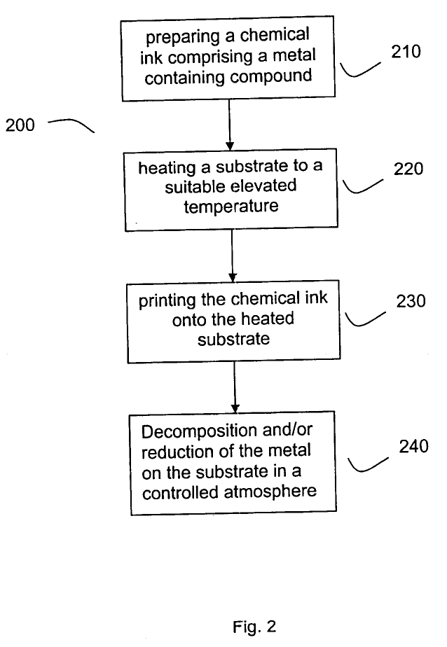

FIG. 2 illustrates an embodiment of the method 200 of the present invention. This embodiment includes preparing a chemical ink that includes a metal containing compound via step 210, wherein the chemical ink is to be printed on a substrate. A next step 220 includes heating of the substrate on which a metal trace is to be formed to a suitable elevated temperature. A next step 230 includes printing of the ink onto the heated substrate in order to form an ink drop on the substrate. A final step 240 includes a decomposition and/or reduction 240 of the metal on the substrate in a controlled atmosphere, thereby forming a metal dot on the substrate. In an embodiment, the chemical ink includes a solvent in which the metal containing chemical compound is dissolved and the solvent evaporates due to the elevated temperature of the substrate, either before or parallel to the decomposition of the metal containing compound.

The above-described method offers advantages over the prior art. First of all the method is simple, fast and cheap and in most of the cases, metal lines or other patterns can be directly generated. It is possible to prepare tailor-made devices or flexible patterns which can be composed according to the desired field of application. This means, any circuit pattern can be easily prepared without extensive apparatus layout. Due to this simple printing technique it is easy to control the width and thickness of the printed lines.

Furthermore, the method described here includes a “one-step” trace formation, i.e. printing traces and thermal decomposition on substrate happen almost at the same time. Due to this “one step” procedure, no further working processes are needed and the final substrate is already built. This reduces working costs and time.

In addition, the total turn around time for the manufacture of a circuit is reduced and the reliability of circuits manufactured by such a dry process is improved. Additionally, a relative fine or narrow conductive trace width can be achieved without reliance on masks and etching processes.

Inkjet printing is additive, reducing waste and processing steps compared to subtractive fabrication methods. It is data-driven, requiring no masks, reducing turnaround time over lithographic processes. Inkjet printing is less limited by substrate composition and morphology and can accommodate a greater number of layers and range of materials than can lithography and subsequent semiconductor-based batch processing. The present invention also realizes environmental advantages such as a reduction in the amount of of various chemicals required to be deposed of, and a reduction in the volume of water required during the manufacturing process.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined only by the claims appended hereto.

What is claimed is:

1. A method of forming a metal trace on a substrate comprising:
inkjet printing a chemical ink comprising a metal containing compound on the substrate to form an ink drop thereon;
heating the substrate to a suitable elevated temperature, wherein
the ink drop undergoes at least one of decomposition and reduction due to the substrate temperature to form a metal on the surface in an controlled atmosphere.

2. The method of claim 1, wherein the metal containing compound comprises at least one organometallic compound which is decomposable to form a pure metal.

3. The method of claim 2, wherein the organometallic compound comprises a transition metal of group 3 to 10 of the Periodic Table (IUPAC) or group 13 of the Periodic Table (IUPAC).

4. The method of claim 3, wherein the organometallic compound comprises a transition metal selected from the group comprising aluminum, copper, gold, nickel and platinum.

5. The method of claim 4, wherein the organometallic compound is a aluminum compound of the general formula Al(R¹)₃, wherein R¹ is independently selected from hydrogen, methyl, ethyl, propyl, butyl, pentyl and isomers thereof.

6. The method of claim 5, wherein the aluminum compound is selected from the group comprising trimethylaluminum, triethylaluminum, triisobutylaluminum (TIBA), diisobutylaluminum hydride (DIBAH) and tripropylaluminum.

7. The method of claim 4, wherein the organometallic compound is a copper compound selected from the group comprising β-diketones of Cu and CpCuP(R²)₃, wherein P is phosphor, Cp is cyclopentadienyl, and R² is independently selected from hydrogen, methyl, ethyl, propyl, butyl, pentyl and isomers thereof.

8. The method of claim 7, wherein the copper compound is selected from the group consisting of copper formate and copper acetylacetonate [Cu(acac)₂].

9. The method of claim 8, wherein the copper compound is [Cu(acac)₂].

10. The method of claim 4, wherein the organometallic compound is a gold methyl compound.

11. The method of claim 10, wherein the gold methyl compound is selected from the group comprising dimethylgold-(III)-acetylacetonate [Me₂Au(acac)], dimethylgoled-(III)-trifluoacetylacetonate [Me₂Au(tfac)] and dimethylgold-(III)-hexafluoroacetylacetonate [Me₂Au(hfac)].

12. The method of claim 4, wherein the organometallic compound is a nickel compound selected from the group comprising Ni(CO)₄, Ni(R²)₂ and Ni(C₅HF₆O₂)₂, wherein R² can be methyl, ethyl, cyclopentadienyl.

13. The method of claim 4, wherein the organometallic compound is selected from the group comprising dimethylethylamine alane, Pt(CH₂(COCH₃)₂), CpPt(R³)₃, wherein Pt is platinum, Cp is cyclopentadienyl, and R³ are independently selected from the group comprising methyl, ethyl, propyl, butyl, pentyl and isomers thereof.

14. The method of claim 1, wherein the chemical ink comprises a solvent.

15. The method of claim 14, wherein the solvent is selected form the group consisting of an organic solvent, a water-based solvent, water, and mixtures thereof.

16. The method of claim 15, wherein the water-based solvent is selected from the group comprising nitrogen-containing ketones, pentandiols and triols.

17. The method of claim 15, wherein the metal containing compound is mixed with the solvent to form the chemical ink.

18. The method of claim 14, wherein the solvent is evaporated after the ink drop has been formed on the surface of the substrate.

19. The method of claim 1, wherein the chemical ink consists of a metal containing compound or a mixture of at least two metal containing compounds.

20. The method of claim 1, wherein the substrate is either an inorganic substrate, an organic substrate, or a combination thereof.

21. The method of claim 20, wherein the inorganic substrate comprises a material selected from the group comprising glass and ceramic.

22. The method of claim 20, wherein the organic substrate comprises a material selected from the group comprising a polymer and paper.

23. The method of claim 22, wherein the polymer is selected from the group comprising polyamide, polycarbonate, and polymeric silicon.

24. The method of claim 1, wherein the thermal printing is performed with a thermal ink jet printer.

25. The method of claim 24, wherein the thermal inkjet printer has a plurality of nozzles.

26. The method of claim 1, wherein the substrate is heated to a temperature in the range of 100 to 500° C.

27. The method of claim 26, wherein the substrate is heated to a temperature in the range of 150 to 450° C.

28. The method of claim 1, wherein the metal trace is a metal line.

29. The method of claim 28, wherein the metal trace is an electrical contact pad on the substrate.

30. The method of claim 28, wherein the metal line is part of an electronic circuit.

31. The method of claim 28, wherein a plurality of metal lines is formed.

32. The method of claim 28, wherein a pattern comprising at least one metal line is formed.
